(19) United States
(12) Patent Application Publication
(10) Pub. No.: US 2025/0176258 A1
(43) Pub. Date: May 29, 2025

(54) SEMICONDUCTOR DEVICE INCLUDING TWO-DIMENSIONAL MATERIAL

(71) Applicant: Samsung Electronics Co., Ltd., Suwon-si (KR)

(72) Inventors: Kyung-Eun BYUN, Suwon-si (KR); Changhyun KIM, Suwon-si (KR); Minsu SEOL, Suwon-si (KR); Minseok YOO, Suwon-si (KR)

(73) Assignee: Samsung Electronics Co., Ltd., Suwon-si (KR)

(21) Appl. No.: 18/882,034

(22) Filed: Sep. 11, 2024

(30) Foreign Application Priority Data
Nov. 28, 2023 (KR) 10-2023-0168242

(51) Int. Cl. H01L 27/092; H01L 29/76

(52) U.S. Cl. CPC H10D 84/856; H10D 48/362

(57) ABSTRACT

Provided is a semiconductor device including a two-dimensional semiconductor material. The semiconductor device includes a first channel including a first two-dimensional material layer, a second channel being apart from the first channel and including a second two-dimensional material layer, a common gate electrode between the first channel and the second channel, a first source electrode and a first drain electrode in contact with the first channel, and a second source electrode and a second drain electrode in contact with the second channel, wherein one of the first channel and the second channel is an N-type channel, and the other is a P-type channel, and the first channel and the second channel are U-shaped.

### CROSS-REFERENCE TO RELATED APPLICATION

This application is based on and claims priority under 35 U. S. C. § 119 to Korean Patent Application No. 10-2023-0168242, filed on Nov. 28, 2023, in the Korean Intellectual Property Office, the disclosure of which is incorporated by reference herein in its entirety.

### BACKGROUND

### 1. Field

The disclosure relates to semiconductor devices including a two-dimensional semiconductor material.

### 2. Description of the Related Art

As the miniaturization of semiconductor devices to improve the integration degree thereof has been in progress, research using two-dimensional materials has recently been conducted. Two-dimensional materials refer to crystal materials within several atomic layers and are studied as substitutes for silicon. Further, the two-dimensional materials are stable even in a nano-scale thickness and have excellent characteristics, and are thus attracting much attention as a next-generation material that may overcome the performance degradation caused by the miniaturization of the semiconductor devices.

### SUMMARY

Provided are semiconductor devices including a two-dimensional semiconductor material.

Additional aspects will be set forth in part in the description which follows and, in part, will be apparent from the description, or may be learned by practice of the presented example embodiments of the disclosure.

According to an example embodiment of the disclosure, a semiconductor device includes a first channel including a first two-dimensional material layer, a second channel being apart from the first channel and including a second two-dimensional material layer, a common gate electrode being between the first channel and the second channel, a first source electrode and a first drain electrode each in contact with the first channel, and a second source electrode and a second drain electrode each in contact with the second channel, wherein one of the first channel and the second channel is an N-type channel, and the other is a P-type channel, and the first channel and the second channel are U-shaped.

Based on a voltage applied to the common gate electrode, any one of the first channel and the second channel may be configured to be selectively turned to an on state, and the other may be configured to be turned to an off state.

When a first voltage is applied to the common gate electrode, between the first channel and the second channel, the N-type channel may be configured to be turned to an on state and the P-type channel may be configured to be turned to an off state.

When a second voltage less than the first voltage is applied to the common gate electrode, between the first channel and the second channel, the N-type channel may be configured to be turned to an off state and the P-type channel may be configured to be turned to an on state.

The first channel and the second channel may be apart from each other in a first direction, and

the first channel and the second channel may be symmetrical to each other in the first direction.

The semiconductor device may further include a gate insulating layer between the first channel and the common gate electrode and between the second channel and the common gate electrode.

An insulator may be between the first source electrode and the first drain electrode and between the second source electrode and the second drain electrode, and the insulator may include at least one of silicon oxide, silicon nitride, silicon carbide, or hexagonal boron nitride (h-BN).

Each of the first channel and the second channel may be doped with any one of an N-type dopant or a P-type dopant.

At least one of the first channel or the second channel may further include a carrier providing layer to provide a carrier to a corresponding one of the first two-dimensional material layer and the second two-dimensional material layer.

The first channel may include a first carrier providing layer, as the carrier proving layer, to provide an electron to the first two-dimensional material layer included in the first channel.

The first carrier providing layer may include at least one of WO3, Ca2N, Sr2N, Ba2N, Y2C, Gd2C, Tb2C, Dy2C, Ho2C, Mn2NO2H2, Mn2CO2H2, V2CO2H2, Ti4C2O2H2, Ti2CO2H2, Ti2NO2H2, Ti4N3O2H2, Y4N3F2, Hf3C2F2, or Zr3C2F2.

The second channel may include a second carrier providing layer, as the carrier providing layer, to provide a hole to the second two-dimensional material layer included in the second channel.

The second carrier providing layer may include at least one of RuCl3, NbS2, MoO3, Cr2C2O2, V2CF2, Y2CO2, Hf3C2O2, Y4C3O2, VS2, Ti4C3O2, Ti3C2O2, Cr4N3O2, V3C2O2, Mn2NO2, V4C3O2, Mn4N3O2, or V2CO2.

The first two-dimensional material layer and the second two-dimensional material layer may include the same two-dimensional semiconductor material.

The same two-dimensional semiconductor material may include a metal element including at least one of Mo, W, Nb, V, Ta, Ti, Zr, Hf, Tc, Re, Cu, Ga, In, Sn, Ge, or Pb and a chalcogen element including at least one of S, Se, or Te.

Thicknesses of the first two-dimensional material layer and the second two-dimensional material layer may be 3 nm or less.

The semiconductor device may further include a first region including the first channel, the first source electrode, the first drain electrode, and the common gate electrode, and a second region including the second channel, the second source electrode, the second drain electrode, and the common gate electrode, wherein the first region and the second region may be fin-shaped.

The first source electrode, the first drain electrode, the second source electrode, the second drain electrode, and the common gate electrode may be on a same plane.

According to an example embodiment of the disclosure, an electronic apparatus including the aforementioned semiconductor device may be provided.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 illustrates a semiconductor device according to an example embodiment;

FIG. 2 is a cross-sectional view taken along line A-A′ of FIG. 1;

FIG. 3 is a cross-sectional view taken along line B-B′ of FIG. 1;

FIG. 4 illustrates a semiconductor device according to an example embodiment;

FIG. 5 illustrates a semiconductor device according to an example embodiment;

FIG. 6 is a circuit diagram illustrating a circuit structure of an inverter of FIG. 1;

FIG. 7 is a circuit diagram of a CMOS SRAM device according to an example embodiment; and

FIG. 8 is a circuit diagram of a CMOS NAND circuit according to an example embodiment.

### DETAILED DESCRIPTION

Reference will now be made in detail to some example embodiments, which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, some example embodiments will be described in detail with reference to the accompanying drawings. In the drawings, like reference numerals refer to the like elements, and sizes of elements in the drawings may be exaggerated for clarity and convenience of explanation. The following example embodiments described below are merely illustrative, and various modifications may be possible from the example embodiments of the present disclosure.

It will be understood that when an element or layer is referred to as being “on” or “above” another element or layer, the element or layer may be directly on, under, on the left side of, or on the right side of another element or layer or intervening elements or layers may exist between the element or layer and another element or layer. The singular forms are intended to include the plural forms as well, unless the context clearly indicates otherwise. Also, it should be understood that, when a part “comprises” or “includes” an element in the specification, unless otherwise defined, other elements are not excluded from the part and the part may further include other elements.

The term “above” and similar directional terms may be applied to both singular and plural. Also, the steps of all methods described herein can be performed in any suitable order unless otherwise indicated herein or otherwise clearly contradicted by context. Example embodiments are not limited to the described order of the steps.

Also, in the specification, the term “units” or “ . . . modules” denote units or modules that process at least one function or operation, and may be realized by hardware, software, or a combination of hardware and software.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

The connection or connection members of the lines between the elements shown in the drawing are examples of functional connection and/or physical or circuit connections, and may be replaced or be implemented as various functional connections, physical connections, or circuit connections in an actual apparatus.

The use of any and all examples, or example language provided herein, is intended merely to better illuminate example embodiments and does not pose a limitation on the scope of example embodiments unless otherwise claimed.

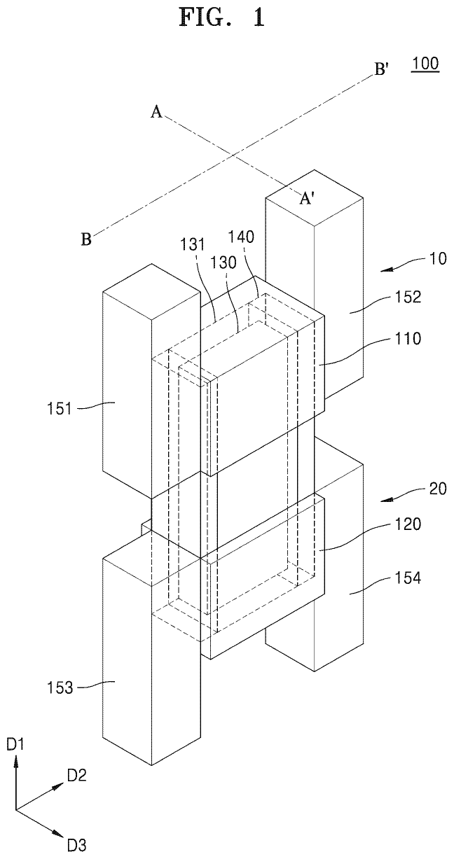

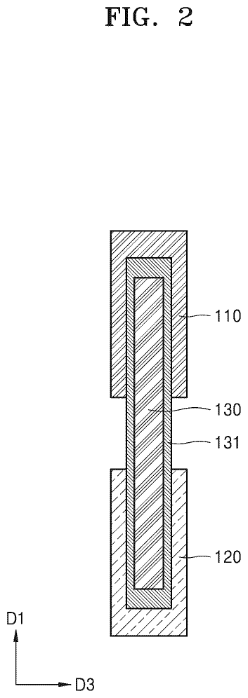

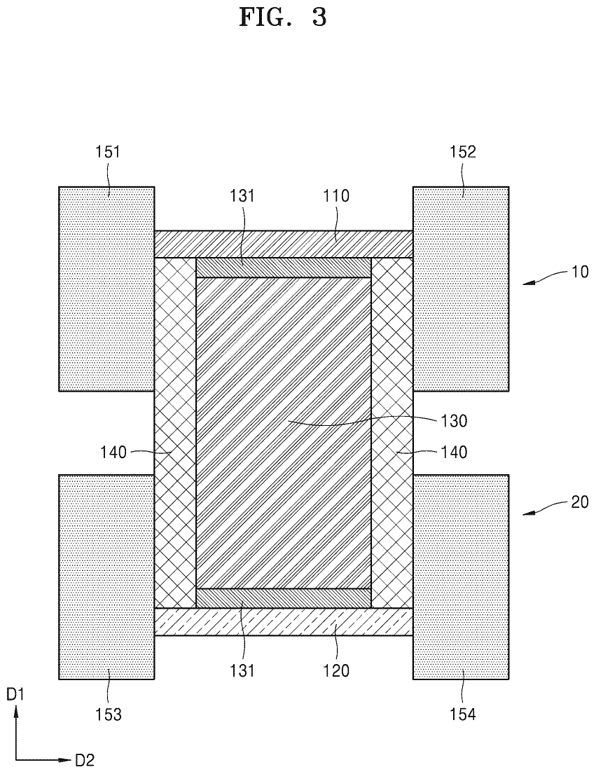

FIG. 1 illustrates a semiconductor device according to an example embodiment. FIG. 2 is a cross-sectional view taken along line A-A′ of FIG. 1. FIG. 3 is a cross-sectional view taken along line B-B′ of FIG. 1.

Referring to FIGS. 1 to 3, a semiconductor device may include a first channel 110 including a first two-dimensional material layer, a second channel apart from the first channel and including a second two-dimensional material layer, a common gate electrode 130 arranged between the first channel 110 and the second channel 120, a first source electrode 151 and a first drain electrode 152 in contact with the first channel 110, and a second source electrode 153 and a second drain electrode 154 in contact with the second channel 120, wherein any one of the first channel 110 and the second channel 120 is an N-type channel, the other one is a P-type channel, and the first channel 110 and the second channel 120 may have a U-shaped form.

A first transistor 10 may include the first channel 110 and a first source electrode 151 and a first drain electrode 152 arranged at one end and the other end of the first channel 110, respectively. A second transistor 20 may include the second channel 120 apart from the first channel 110 along a first direction D1 and the second source electrode 153 and the second drain electrode 154 arranged at one end and the other end of the second channel 120, respectively.

For example, a first region including portions of the first channel 110, the first source electrode 151, the first drain electrode 152, and the common gate electrode 130, and a second region including portions of the second channel 120, the second source electrode 153, the second drain electrode 154 may be provided, and the first region or the second region may be U-shaped. For example, one of the first region and the second region may be fin-shaped, and the other may have a transistor shape including a buried channel. In this case, the first region and the second region may correspond to all or part of the first transistor 10 and the second transistor 20 described above. Transistors or semiconductor devices including the fin forms described above may be fin field effect transistors (FinFETs) or multi-bridge channel field effect transistors (MBCFETs), but are not necessarily limited thereto.

The FinFET, which is a transistor having a fin form, is a semiconductor device having a three-dimensional structure to enhance information processing speed and power consumption efficiency. A semiconductor chip structure of the related art is formed in a plane (2D), and a portion protruding due to the semiconductor chip structure designed to have a three-dimensional (3D) structure may have a shape like a fin of a fish, thereby increasing a contact area between a gate electrode and a channel and thus enhancing information processing speed and power consumption efficiency.

The common gate electrode 130 may be arranged between the first region and the second region, and the first region and the second region may be inverters or semiconductor devices having different doping types. Details are described below.

The common gate electrode 130 and a gate insulating layer 131 may be arranged between the first channel 110 and the second channel 120, and the common gate electrode 130 and the gate insulating layer 131 may be arranged side by side or sequentially in the first direction D1 or a second direction D2. The first channel 110 and the second channel 120 may have different types, and one may be of N type and the other may be of P type. For example, the first channel 110 and the second channel 120 may be doped with different dopants from each other and have different types, or the first channel 110 and the second channel 120 may include the same two-dimensional material layer but have different types according to carrier providing layers 141a and 141b (hereinafter, also referred to as the first carrier providing layer 141a and the second carrier providing layer 141b) described below. In addition, the channels may be formed in different types, even though the channels include the same dopant, according to carriers of the carrier providing layers 141a and 141b and constituent materials of each channel, or the channels may be formed in different types, when the channels include different dopants from each other, according to the content of oxygen included in an insulator 140 of each channel. However, example embodiments are not limited thereto.

The first source electrode 151 and the first drain electrode 152 may be arranged on one side (e.g., an outside) of the first channel 110 and above the second channel 120, and the second source electrode 153 and the second drain electrode 154 may be arranged on one side (e.g., an outside) of the second channel 120 and below the first channel 110. The first channel 110 may be arranged between the first source electrode 151 and the first drain electrode 152, and the second channel 120 may be arranged between the second source electrode 153 and the second drain electrode 154.

The first channel 110 and the second channel 120 may include two-dimensional semiconductor material layers of about 1 to 10 layers (or 1 to 5 layers). That is, the first channel 110 and the second channel 120 may include a single two-dimensional semiconductor material layer or may have a structure in which a plurality of two-dimensional semiconductor material layers are stacked in about 10 or less layers (or about 5 or less layers). Even if a few layers of two-dimensional semiconductor materials of about 10 or less layers are stacked, the unique physical properties of the two-dimensional semiconductor material may be maintained.

The first channel 110 may include a first two-dimensional material layer and the second channel 120 may include a second two-dimensional material layer. The two-dimensional semiconductor materials included in the first channel 110 and the second channel 120 refer to two-dimensional materials having a layered structure in which the constituent atoms are two-dimensionally bonded. The two-dimensional semiconductor material has excellent electrical properties and may maintain a high mobility without undergoing a great change in the characteristics even when the thickness is reduced to a nano-scale.

Transition Metal Dichalcogenides (TMD) is a two-dimensional material with semiconductor characteristics and is a compound of a transition metal and chalcogen elements. Here, the transition metal may include, for example, at least one of Mo, W, Nb, V, Ta, Ti, Zr, Hf, Co, Tc, or Re, and the chalcogen element may include, for example, at least one of S, Se, or Te. For example, the TMD may include MoS2, MoSe2, MoTe2, WS2, WSe2, WTe2, ZrS2, ZrSe2, HfS2, HfSe2, NbSe2, or ReSe2. However, example embodiments are not limited thereto.

The first channel 110 may be a P-type semiconductor and the second channel 120 may be an N-type semiconductor. In this case, the first metal chalcogenide-based material of the first channel 110 and the second metal chalcogenide-based material of the second channel 120 may include different metal elements from each other. In addition, the first metal chalcogenide-based material of the first channel 110 and the second metal chalcogenide-based material of the second channel 120 may include the same chalcogen element. The first channel 110 may include a first metal element and a first chalcogen element and the second channel 120 may include a second metal element and a second chalcogen element. Here, the first metal element and the second metal element may be different from each other and the first chalcogen element and the second chalcogen element may be the same. When a metal element changes in a metal chalcogenide material, the conductive type (P and N) may change. That is, if the first channel 110 is P type and the second channel 120 is N type, the metal elements thereof may be different. In some example embodiments, the conductive type (P and N) of some metal elements may be changed due to a change in the chalcogen element bonded to the metal element. Therefore, in some cases, the first metal element and the second metal element may be the same, and the first chalcogen element and the second chalcogen element may be different. However, the first channel 110 does not need to be a P-type semiconductor and the second channel 120 does not need to be an N-type semiconductor.

The first channel 110 may include, as metal chalcogenide-based materials having P-type semiconductor characteristics, at least one of WS2, ZrS2, ZrSe2, HfS2, HfSe2, or NbSe2. The second channel 120 may include, as a metal chalcogenide-based material having N-type semiconductor characteristics, at least one of MoS2, MoSe2, MoTe2, WSe2, or WTe2. For example, the first channel 110 may include WS2 having P-type semiconductor characteristics, and the second channel 120 may include MoS2 having N-type semiconductor characteristics. The first channel 110 and the second channel 120 may each include any one of an N-type semiconductor or a P-type semiconductor, and if one includes the N-type semiconductor, the other may include the P-type semiconductor. However, the first channel 110 and the second channel 120 does not necessarily need to be a P-type semiconductor and an N-type semiconductor (or an N-type semiconductor and a P-type semiconductor), respectively.

At least one of the first channel 110 and the second channel 120 may be doped with a P-type dopant or an N-type dopant. If the first channel 110 is a P-type semiconductor, the P-type dopant may be doped on the first channel 110, and in some cases, the N-type dopant may be doped on the first channel 110. Similarly, if the second channel 120 is an N-type semiconductor, an N-type dopant or a P-type dopant may be doped on the second channel 120. For example, if the first channel 110 is WS2 (P-type), AuCl3, which is a P-type dopant, or K, which is an N-type dopant, may be doped on the first channel 110. That is, the same type of dopant or opposite types of dopants may be doped. By doping opposite types of dopants, the semiconductor type of a material may also be changed.

In addition, each of the first channel 110 and the second channel 120 may have a single-layer structure (a two-dimensional plane structure) or a structure in which a plurality of single-layer structures (the two-dimensional plane structures) are stacked. Even if a plurality of single-layer structures are stacked, the characteristics of the two-dimensional material may be maintained. In terms of electric structure, a two-dimensional material may be defined as a material of which density of state (DOS) depends on quantum well behavior. In a material having a structure in which a plurality of two-dimensional unit material layers (about 100 or less layers) are stacked, the DOS may depend on a quantum well behavior. Thus, the material having the structure in which a plurality of single-layer structures (the two-dimensional plane structure) are stacked may also be referred to as a “two-dimensional material”.

The first channel 110 and the second channel 120 may extend in the first direction D1, the second direction D2 perpendicular to the first direction D1, and/or a third direction D3 perpendicular to both the first direction D1 and the second direction D2. For example, the first channel 110 and the second channel 120 may extend along the surface of the common gate electrode 130 and may be formed in a U-shape. In this case, the first direction D1 may be vertical with respect to the surface of the substrate (not shown).

The first channel 110, the second channel 120, and the common gate electrode 130 may be arranged along the first direction D1, and when a semiconductor device 100 is viewed in the first direction D1, the first channel 110, the second channel 120, and the common gate electrode 130 may overlap each other in the first direction D1. That is, the first transistor 10 and the second transistor 20 may overlap in the first direction D1. In addition, the first source electrode 151, the common gate electrode 130, and the first drain electrode 152 may be arranged along the second direction D2, and the second source electrode 153, the common gate electrode 130, and the second drain electrode 154 may be arranged along the second direction D2. When the semiconductor device 100 is viewed in the second direction D2, the first source electrode 151, the common gate electrode 130, and the first drain electrode 152 may overlap each other in the second direction D2, and the second source electrode 153, the common gate electrode 130, and the second drain electrode 154 may overlap each other in the second direction D2. Due to the overlapping features described above, an empty space in the semiconductor device 100 may be reduced and the integration of the semiconductor device 100 may be improved.

The first source electrode 151 and the first drain electrode 152 each may be provided at an end of the first channel 110 (e.g., the first source electrode 151 and the first drain electrode 152 may be provided at opposite ends of the first channel in the second direction D2, respectively), and the second source electrode 153 and the second drain electrode 154 may be provided at an end of the second channel 120 (e.g., the second source electrode 153 and the second drain electrode 154 may be provided at opposite ends of the second channel in the second direction D2, respectively). The common gate electrode 130 may be arranged between the first channel 110 and the second channel 120. The common gate electrode 130 may be in contact with both the first channel 110 and the second channel 120. The first source electrode 151, the second source electrode 153, the first drain electrode 152, the second drain electrode 154, and the common gate electrode 130 may be formed of various metals or metal compounds. In addition, the first source electrode 151, the second source electrode 153, the first drain electrode 152, the second drain electrode 154, and the common gate electrode 130 may be formed of conductive two-dimensional materials or bulk materials that are not two-dimensional materials. The gate insulating layer 131 may be arranged between the common gate electrode 130 and the first and second channels 110 and 120. The gate insulating layer 131 may be arranged on the common gate electrode 130, and the first and second channels 110 and 120 may be arranged apart from each other and on the gate insulating layer 131.

The common gate electrode 130 may be a type of conductive substrate. The common gate electrode 130 may be formed of a conductive two-dimensional material or may be formed of a material (hereinafter, a bulk material) that is not a two-dimensional material. For example, the common gate electrode 130 may be formed of metal such as Cu, Ni, Fe, Co, Pt, Ru, etc. or may be formed of graphene. In some example embodiments, the common gate electrode 130 may be formed of a doped silicon (Si). The gate insulating layer 131 may be formed of a two-dimensional insulating material or a bulk material that is not a two-dimensional material. The gate insulating layer 131 may include at least one of high-k oxide, silicone oxide, or a two-dimensional insulating material. The gate insulating layer 131 may be high-k oxide and may include, for example, aluminum oxide, hafnium oxide, zirconium hafnium oxide, or lanthanum oxide. The gate insulating layer 131 may include, for example, hexagonal boron nitride (h-BN) as a two-dimensional insulating material. However, example embodiments are not limited thereto. However, in some cases, the gate insulating layer 131 may include an insulating material such as SiO2, SiNx, AlN, Al2O3, HfO2, or ZrO₂. The common gate electrode 130 and the gate insulating layer 131 may be combined and considered as one substrate. In some example embodiments, a separate substrate (not shown) may be further provided under the common gate electrode 130.

For example, a substrate (not shown) may be arranged on one side of the first transistor and the second transistor. Channels may be arranged on the substrate (not shown). The substrate (not shown) may include various materials such as semiconductor materials, insulating materials, and metal materials. When the first channel 110 and the second channel 120 including the two-dimensional semiconductor material layer are formed by depositing a two-dimensional semiconductor material on the substrate (not shown), the substrate (not shown) may be a substrate for growing the semiconductor material.

The insulator 140 may be arranged between the first channel 110 and the second channel 120. The insulator 140 may include silicon oxide, silicon nitride, silicon carbide, or a two-dimensional material. In this case, the insulator 140 may include, for example, h-BN. However, the material of the insulator 140 is not limited to h-BN, but may be variously modified. In addition, the material of the insulator 140 may not be a two-dimensional material.

The insulator 140 may include a low-k material. The dielectric constant of the insulator 140 may be about 3 to about 5. However, example embodiments are not limited thereto.

The first channel 110, the common gate electrode 130, the gate insulating layer 131, the first source electrode 151, and the first drain electrode 152 may form the first transistor 10. The first transistor 10 may be a P-type transistor. The second channel 120, the common gate electrode 130, the gate insulating layer 131, the second source electrode 153, and the second drain electrode 154 may form the second transistor 20. The second transistor 20 may be an N-type transistor. Depending on the voltage applied to the common gate electrode 130, the electrical barrier of the first channel 110 may be controlled, and the on/off of the first transistor may be controlled. Similarly, depending on the voltage applied to the common gate electrode 130, the electrical barrier of the second channel 120 may be controlled, and the on/off of the second transistor may be controlled. If the thickness of the first channel 110 and the second channel 120 is relatively thin (e.g., about 5 nm or less), the first transistor and the second transistor may be tunneling barrier devices, and if the thickness of the first channel 110 and the second channel 120 is relatively thick (e.g., tens of nm), the first transistor and the second transistor may be a Schottky barrier device. In addition, the thickness of the first two-dimensional material layer and the second two-dimensional material layer may be about 3 nm or less, but is not limited thereto.

The semiconductor device 100 according to an example embodiment may act as an inverter in which, based on the voltage applied to the common gate electrode 130, any one of the first channel 110 and the second channel 120 is selectively in an on-state current and the other one is in an off-state current. For example, when a first voltage is applied to the common gate electrode 130, between the first channel 110 and the second channel 120, the N-type channel may be turned to an on state and the P-type channel may be turned to an off state, and when a second voltage less than the first voltage is applied to the common gate electrode 130, between the first channel 110 and the second channel 120, the N-type channel may be turned to an off state and the P-type channel may be turned to an on state.

The semiconductor device 100 according to an example embodiment may be a complementary metal oxide semiconductor (CMOS) inverter. The CMOS inverter has a structure in which gates of NMOSFET and PMOSFET are connected to each other to receive an input voltage (Vin), and drains of NMOSFET and PMOSFET are connected to each other to output an output voltage (Vout).

The first source electrode 151 or the second source electrode 153 may be connected to a power terminal VDD. The first drain electrode 152 or the second drain electrode 154 may be connected to a ground terminal VSS. In other words, the first drain electrode 152 or the second drain electrode 154 may be grounded. The common gate electrode 130 may be connected to an input terminal VIN. The first drain electrode 152 or the second drain electrode 154 may be connected to an output terminal VOUT. The on/off state of the first transistor 10 and the second transistor 20 may be controlled according to an input signal (voltage) applied to the common gate electrode 130 through the input terminal VIN, and a signal output through the output terminal VOUT may change. For example, when a signal corresponding to ‘1’ is input into the input terminal VIN, a signal corresponding to ‘0’ may be output through the output terminal VOUT. In addition, when a signal corresponding to ‘0’ is input into the input terminal VIN, a signal corresponding to ‘1’ may be output through the output terminal VOUT. Therefore, the device of FIG. 1 may act as an inverter.

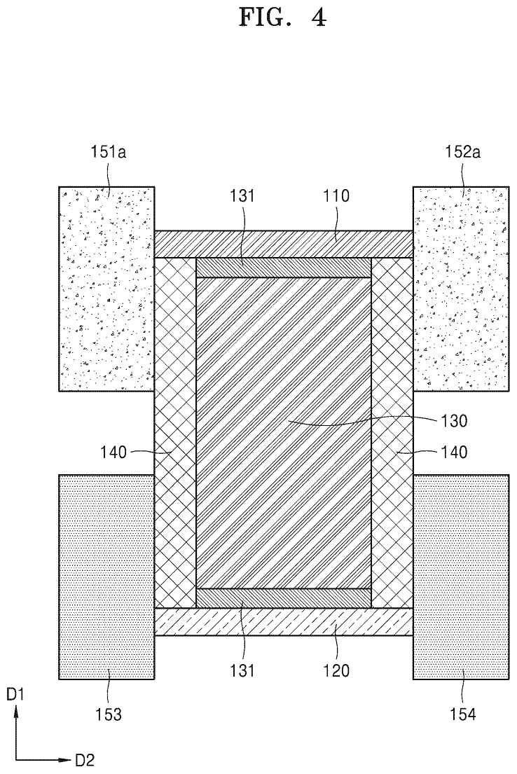

FIG. 4 illustrates a semiconductor device according to an example embodiment.

Referring to FIG. 4, a first source electrode 151a and a first drain electrode 151b may be provided as contact metals for the common gate electrode 130, and the materials included in the first channel 110 and the second channel 120 are the same as the materials described with reference to FIGS. 1 to 3.

The first source electrode 151a and the first drain electrode 151b may, as contact metals, control the constituent material or dopant to determine the type of the first transistor 10 and the first channel 110. For example, when a major carrier is adjusted to be an electron in the first source electrode 151a as a contact metal, the first transistor 10 and the first channel 110 may have an N type. When a major carrier is adjusted to be a hole in the first source electrode 151a as a contact metal, the first transistor 10 and the first channel 110 may have a P-type.

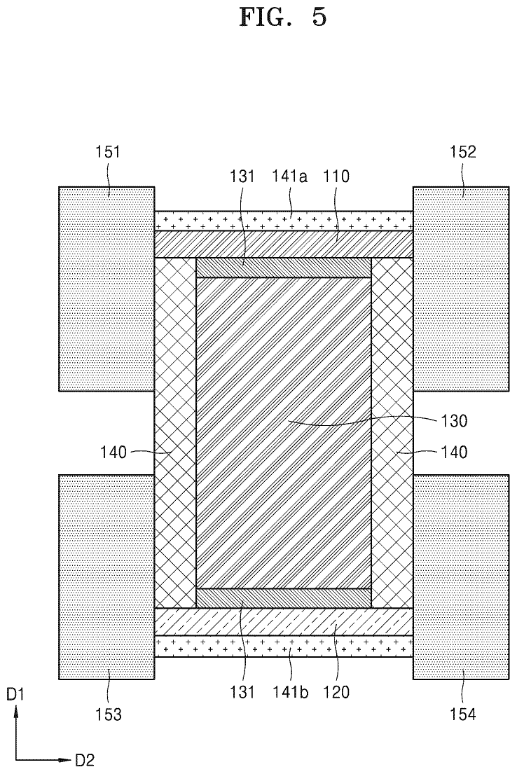

FIG. 5 illustrates a semiconductor device according to an example embodiment.

Referring to FIG. 5, an interface layer formed on one side of the first channel 110 and on one side of the second channel 120 of the semiconductor device of FIGS. 1 to 3 may further be included. In this case, the interface layer may include a carrier providing layer to provide a carrier to a channel of the semiconductor device. For example, at least one of the first channel 110 and the second channel 120 may further include a carrier providing layer to provide a carrier to a corresponding one or corresponding ones of the first two-dimensional material layer and the second two-dimensional material layer. The carrier providing layer may be arranged on one side of the first channel 110 and the second channel 120 including the two-dimensional material layer. The carrier providing layer may provide a carrier (e.g., an electron or hole) to the first channel 110 including the first two-dimensional material layer and the second channel 120 including the second two-dimensional material layer. In addition, the carrier providing layer may include a two-dimensional insulating material. Because the carrier providing layer includes the two-dimensional insulating material, the volume of the semiconductor device 100 may be reduced. For example, the thickness of the carrier providing layer may be less than the thickness of the first channel 110 including the first two-dimensional material layer and the second channel 120 including and the second two-dimensional material layer. Because the carrier providing layer includes a two-dimensional insulating material and is stable, the material of the carrier providing layer may be alleviated or prevented from spreading into the two-dimensional material layer having semiconductor characteristics.

The first channel 110 may include the first carrier providing layer 141a to provide an electron to the first two-dimensional material layer. In this case, the first carrier providing layer 141a may include at least one of WO3, Ca2N, Sr2N, Ba2N, Y2C, Gd2C, Tb2C, Dy2C, Ho2C, Mn2NO2H2, Mn2CO2H2, V2CO2H2, Ti4C2O2H2, Ti2CO2H2, Ti2NO2H2, Ti4N3O2H2, Y4N3F2, Hf3C2F2, or Zr3C2F2, but is not limited to the above materials. The second channel 120 may include a second carrier providing layer 141b providing a hole in the second two-dimensional material layer. In this case, the first carrier providing layer 141a may include at least one of RuCl3, NbS2, MoO3, Cr2C2O2, V2CF2, Y2CO2, Hf3C2O2, Y4C3O2, VS2, Ti4C3O2, Ti3C2O2, Cr4N3O2, V3C2O2, Mn2NO2, V4C3O2, Mn4N3O2, or V2CO2, but is not limited to the above materials.

Even when the material of the first channel 110 and the second channel 120 is the same, the types of the first channel 110 and the second channel 120 may be determined according to a desired (or alternatively, predetermined) interface layer inserted into (or provided on) one side of the first channel 110 and one side of the second channel 120. In this case, the material of the interface layer may include aluminum oxide, but is not necessarily limited thereto. The physical properties of the interface layer may be determined by controlling the composition of the oxide element and the aluminum element of aluminum oxide included in the interface layer, and the types of the first channel 110 and the second channel 120 may be determined according to the physical properties of the interface layer of which. That is, when the material of the first channel 110 and the second channel 120 is the same, one of the first channel 110 and the second channel 120 may be an N-type semiconductor, and the other may be a P-type semiconductor. The remaining portions are as described in FIGS. 1 to 3.

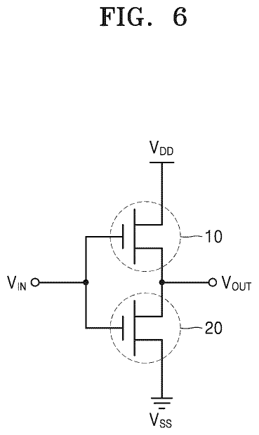

FIG. 6 is a circuit diagram illustrating the circuit structure of the inverter of FIG. 1.

Referring to FIGS. 1 to 3, the first transistor 10 and the second transistor 20 are connected to each other. The first transistor 10 may be a P-type and the second transistor 20 may be an N-type. The power terminal VDD may be connected to the drain of the first transistor 10. The output terminal VOUT may be commonly connected to the source of the first transistor 10 and the drain of the second transistor 20. The ground terminal VSS may be connected to the source of the second transistor 20. The input terminal VIN may be connected to the gate electrode (the common gate electrode) of the first transistor 10 and the second transistor 20. As described above, the on/off state of the first transistor 10 and the second transistor 20 may be controlled according to an input signal (voltage) applied to the common gate electrode 130 through the input terminal VIN, and a signal output through the output terminal VOUT may change. The circuit structure of FIGS. 1 to 3 may be equally applied to the structure of FIGS. 4 and 5.

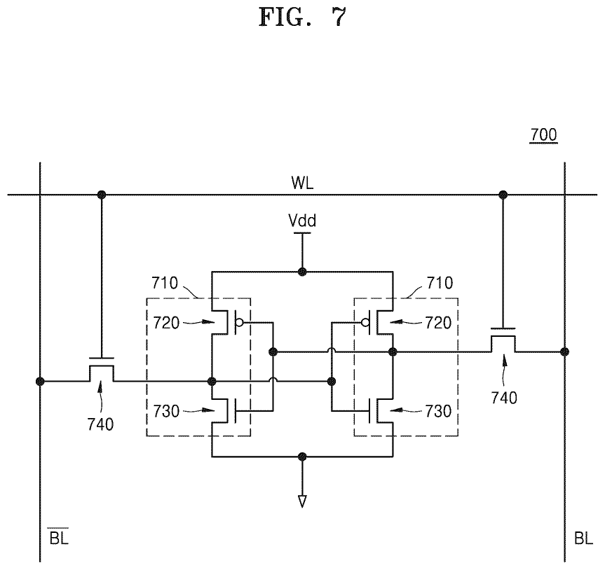

FIG. 7 is a circuit diagram of a CMOS SRAM device 700 according to an example embodiment.

Referring to FIG. 7, the CMOS SRAM device 700 includes a pair of driving transistors 710. The pair of driving transistors 710 respectively include a PMOS transistor 720 and an NMOS transistor 730 connected between a power terminal Vdd and a ground terminal. The CMOS SRAM device 700 may further include a pair of transfer transistors 740. A transfer transistor 740 is cross-connected to a common node of the PMOS transistor 720 and the NMOS transistor 730 forming the driving transistor 710. The power terminal Vdd is connected to a source of the PMOS transistor 720 and the ground terminal is connected to a source of the NMOS transistor 730. A word line WL is connected to a gate of the pair of transfer transistors 740, and a bit line BL and a reversed (or complementary) bit line may be connected to the drains of the pair of transfer transistors 740, respectively. At least one of the driving transistor 710 and the transfer transistor 740 of the CMOS SRAM device 700 may include any of the semiconductor devices according to the example embodiments described above with reference to FIGS. 1 to 5 or a semiconductor device made by modifying and combining the above semiconductor devices.

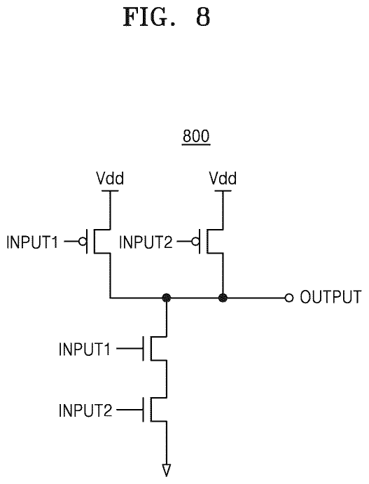

FIG. 8 is a circuit diagram of a CMOS NAND circuit according to an example embodiment.

Referring to FIG. 8, the CMOS NAND circuit 800 includes a pair of CMOS transistors in which different input signals are transmitted. The CMOS NAND circuit 800 may include any of the semiconductor devices according to the example embodiments described above with reference to FIGS. 1 to 5 or a semiconductor device made by modifying and combining the above semiconductor devices.

According to the example embodiments, the semiconductor device may include a first channel including a first two-dimensional material layer, a second channel being apart from the first channel and including a second two-dimensional material layer, a common gate electrode arranged between the first channel and the second channel, a first source electrode and a first drain electrode in contact with the first channel, and a second source electrode and a second drain electrode in contact with the second channel, wherein any one of the first channel and the second channel is an N-type channel, the other one is a P-type channel, the first channel and the second channel may have a U-shaped form, and the plurality of electrodes or the plurality of channels may overlap each other in any one direction of the first direction and the second direction to reduce the space of the semiconductor device to improve the integration of the semiconductor device.

In addition, the semiconductor device according to an example embodiment may be an inverter including the first transistor and the second transistor, and a variety of logical devices may be implemented using the inverter, in which case, the performance and operation characteristics of the logic device may be improved.

However, example embodiments of the disclosure are not limited to the example embodiments described above.

The semiconductor devices and the electronic apparatuses including the same are described above with reference to the drawings, but the descriptions are merely illustrative examples, and it will be understood by those of ordinary skill in the art that various changes in form and details are possible.

It should be understood that some example embodiments described herein should be considered in a descriptive sense only and not for purposes of limitation. Descriptions of features or aspects within each of the described example embodiments should typically be considered as available for other similar features or aspects in other example embodiments. While one or more example embodiments have been described with reference to the figures, it will be understood by one of ordinary skill in the art that various changes in form and details may be made therein without departing from the spirit and scope as defined by the following claims.

What is claimed is:

1. A semiconductor device comprising:
a first channel comprising a first two-dimensional material layer;
a second channel being apart from the first channel and including a second two-dimensional material layer;
a common gate electrode between the first channel and the second channel;
a first source electrode and a first drain electrode each in contact with the first channel; and
a second source electrode and a second drain electrode each in contact with the second channel, wherein
one of the first channel and the second channel is an N-type channel, and the other is a P-type channel, and
the first channel and the second channel are U-shaped.

2. The semiconductor device of claim 1, wherein, based on a voltage applied to the common gate electrode, any one of the first channel and the second channel is configured to be selectively turned to an on state and the other is configured to be turned to an off state.

3. The semiconductor device of claim 1, wherein, when a first voltage is applied to the common gate electrode, between the first channel and the second channel, the N-type channel is configured to be turned to an on state and the P-type channel is configured to be turned to an off state.

4. The semiconductor device of claim 3, wherein, when a second voltage less than the first voltage is applied to the common gate electrode, between the first channel and the second channel, the N-type channel is configured to be turned to an off state and the P-type channel is configured to be turned to an on state.

5. The semiconductor device of claim 1, wherein
the first channel and the second channel are apart from each other in a first direction, and
the first channel and the second channel are symmetrical to each other in the first direction.

6. The semiconductor device of claim 1, further comprising:
a gate insulating layer between the first channel and the common gate electrode and between the second channel and the common gate electrode.

7. The semiconductor device of claim 1, wherein
an insulator is between the first source electrode and the first drain electrode and between the second source electrode and the second drain electrode, and
the insulator comprises at least one of silicon oxide, silicon nitride, silicon carbide, or hexagonal boron nitride (h-BN).

8. The semiconductor device of claim 1, wherein each of the first channel and the second channel is doped with any one of an N-type dopant or a P-type dopant.

9. The semiconductor device of claim 1, wherein at least one of the first channel or the second channel further comprises a carrier providing layer to provide a carrier to a corresponding one of the first two-dimensional material layer and the second two-dimensional material layer.

10. The semiconductor device of claim 9, wherein the first channel comprises a first carrier providing layer, as the carrier providing layer, to provide an electron to the first two-dimensional material layer included in the first channel.

11. The semiconductor device of claim 10, wherein the first carrier providing layer comprises at least one of WO3, Ca2N, Sr2N, Ba2N, Y2C, Gd2C, Tb2C, Dy2C, Ho2C, Mn2NO2H2, Mn2CO2H2, V2CO2H2, Ti4C202H2, Ti2CO2H2, Ti2NO2H2, Ti4N302H2, Y4N3F2, Hf3C2F2, or Zr3C2F2.

12. The semiconductor device of claim 9, wherein the second channel comprises a second carrier providing layer, as the carrier providing layer, to provide a hole to the second two-dimensional material layer included in the second channel.

13. The semiconductor device of claim 12, wherein the second carrier providing layer comprises at least one of RuCl3, NbS2, MoO3, Cr2C2O2, V2CF2, Y2CO2, Hf3C2O2, Y4C3O2, VS2, Ti4C3O2, Ti3C2O2, Cr4N3O2, V3C2O2, Mn2NO2, V4C3O2, Mn4N3O2, or V2CO2.

14. The semiconductor device of claim 1, wherein the first two-dimensional material layer and the second two-dimensional material layer comprise a same two-dimensional semiconductor material.

15. The semiconductor device of claim 14, wherein the same two-dimensional semiconductor material comprises a metal element including at least one of Mo, W, Nb, V, Ta, Ti, Zr, Hf, Tc, Re, Cu, Ga, In, Sn, Ge, or Pb and a chalcogen element including at least one of S, Se, and Te.

16. The semiconductor device of claim 1, wherein thicknesses of the first two-dimensional material layer and the second two-dimensional material layer are 3 nm or less.

17. The semiconductor device of claim 1, further comprising:
a first region comprising the first channel, the first source electrode, the first drain electrode, and the common gate electrode; and
a second region comprising the second channel, the second source electrode, the second drain electrode, and the common gate electrode,
wherein the first region and the second region are fin-shaped.

18. The semiconductor device of claim 1, wherein the first source electrode, the first drain electrode, the second source electrode, the second drain electrode, and the common gate electrode are on a same plane.

19. An electronic apparatus comprising the semiconductor device of claim 1.
